(19) United States
(12) Patent Application Publication
(10) Pub. No.: US 2026/0157173 A1
(43) Pub. Date: Jun. 4, 2026

(54) POWER MODULE

(71) Applicant: HYUNDAI MOBIS CO., LTD., Seoul (KR)

(72) Inventors: Seung Jun NOH, Yongin-si (KR); Keun Jae LEE, Yongin-si (KR); Min Ki KIM, Yongin-si (KR); Pil Kyoung OH, Yongin-si (KR)

(73) Assignee: HYUNDAI MOBIS CO., LTD., Seoul (KR)

(21) Appl. No.: 19/314,501

(22) Filed: Aug. 29, 2025

(30) Foreign Application Priority Data
Oct. 11, 2024 (KR) 10-2024-0138545

(51) Int. Cl. H01L 23/367

(52) U.S. Cl. CPC H10W 40/226

(57) ABSTRACT

A power module including an insulating substrate, a heat dissipation part integrally provided on the insulating substrate and a sealing part that seals the insulating substrate and a part of the heat dissipation part.

### CROSS-REFERENCE TO RELATED APPLICATION

This application claims the benefit under 35 U.S.C. §119(a) of priority to Korean Patent Application No. 10-2024-0138545 filed on Oct. 11, 2024, in the Korean Intellectual Property Office, the entire disclosure of which is incorporated herein by reference for all purposes.

### BACKGROUND

### 1. Technical Field

The present disclosure relates to a power module, and more specifically, to a power module capable of improving heat dissipation performance by reducing thermal resistance.

### 2. Related Art

A power semiconductor device is a semiconductor device composed of a power switching device and an integrated circuit (IC) and plays a role in converting, decomposing, and managing the power supplied to an electronic device.

The power semiconductor device requires higher voltage and higher reliability compared to general semiconductor devices. In particular, demand for the power semiconductor devices is increasing due to the development of hybrid and electric vehicles. The power conversion modules used in the hybrid vehicles and electric vehicles may be composed of power semiconductor devices used to convert direct current (DC) to alternating current (AC) or convert AC to DC.

The power modules are implemented through key technologies such as module integration design technology for power semiconductor devices and packaging materials, manufacturing process technology, characteristic testing, and reliability evaluation technology. In particular, the power modules applied to eco-friendly vehicles such as hybrid vehicles and electric vehicles require high reliability because they operate in harsh environments such as high temperatures and vibrations.

The background technology of the present disclosure is disclosed in Korean Patent Registration No. 10-2277800 (registered on Jul. 16, 2021, entitled “HEAT SINK INTEGRATED POWER MODULE AND MANUFACTURING METHOD THEREOF”).

### SUMMARY

Various embodiments are directed to a power module that may improve heat dissipation performance by reducing thermal resistance.

A power module according to an embodiment of the present disclosure includes an insulating substrate, a heat dissipation part integrally provided on the insulating substrate, and a sealing part sealing the insulating substrate and a part of the heat dissipation part.

The heat dissipation part may include a first heat dissipation part integrally provided on a first surface of the insulating substrate and a second heat dissipation part integrally provided on a second surface of the insulating substrate, the second surface facing in a direction opposite to the first surface, and the sealing part may seal the entirety of the insulating substrate and the first heat dissipation part, and a part of the second heat dissipation part.

The first heat dissipation part and the second heat dissipation part may have different volumes.

The volume of the first heat dissipation part and the volume of the second heat dissipation part may be the same.

The second heat dissipation part may include a first heat dissipation body part contacting the second surface and not contacting the sealing part, a second heat dissipation body part extending from the first heat dissipation body and capable of contacting the second surface and the sealing part, and heat dissipation fin parts extending from the first heat dissipation body part in a direction parallel to a first direction, and disposed to be spaced apart from each other along a direction parallel to a second direction crossing the first direction.

The first heat dissipation body part may be disposed on a first part of the second heat dissipation body part, the second heat dissipation body part may be disposed on a second part of the second heat dissipation body part excluding the first part of the second heat dissipation body part, and a height of the second heat dissipation body part parallel to the first direction and a height of the heat dissipation fin part parallel to the first direction may be the same.

A thickness of the first heat dissipation part parallel to the first direction and a thickness of the first heat dissipation body part parallel to the first direction may be different from each other.

The thickness of the first heat dissipation part parallel to the first direction may be greater than the thickness of the first heat dissipation body part parallel to the first direction.

The second heat dissipation body part may include an exposed surface that does not contact the sealing part, and an outer surface of the sealing part adjacent to the exposed surface and the exposed surface may be disposed on a same plane.

The insulating substrate and the heat dissipation part may be disposed in plural numbers to be spaced apart from each other along a direction parallel to a first direction, and the plurality of heat dissipation parts may be disposed to face in opposite directions.

The present disclosure can reduce the thermal resistance of a power module by configuring a heat dissipation part integrally provided on an insulating substrate, thereby improving the heat dissipation performance of the power module and simplifying the components constituting the power module and the structure of the power module.

### BRIEF DESCRIPTION OF THE DRAWINGS

FIG. 1 is a perspective view of a power module viewed from one direction according to a first embodiment of the present disclosure.

FIG. 2 is a perspective view of the power module of FIG. 1 viewed from another direction.

FIG. 3 is a cross-sectional view taken along a line III-III of FIG. 1.

FIG. 4 is a perspective view of a power module viewed from one direction according to a second embodiment of the present disclosure.

FIG. 5 is a perspective view of the power module of FIG. 4 viewed from another direction.

FIG. 6 is a cross-sectional view along a line ?-? of FIG. 4.

### DETAILED DESCRIPTION

Hereinafter, with reference to the accompanying drawings, an embodiment of a power module according to the present disclosure will be described. In this process, the thickness of the lines and the size of the components in the drawings may be exaggeratedly illustrated for clarity and convenience of description. In addition, the terms to be described below are terms defined in consideration of the functions in the present disclosure, and these may vary depending on the intention of the user or operator or custom. Accordingly, the definition of these terms should be made based on the overall contents of the specification.

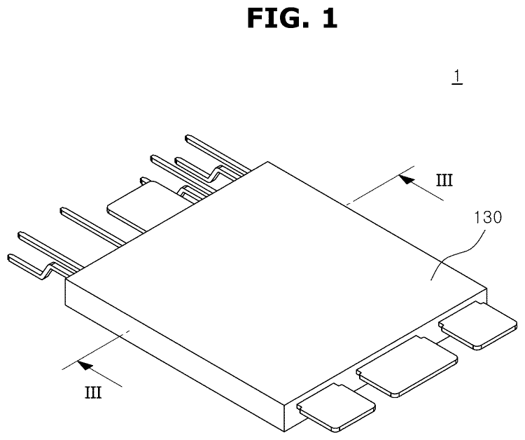

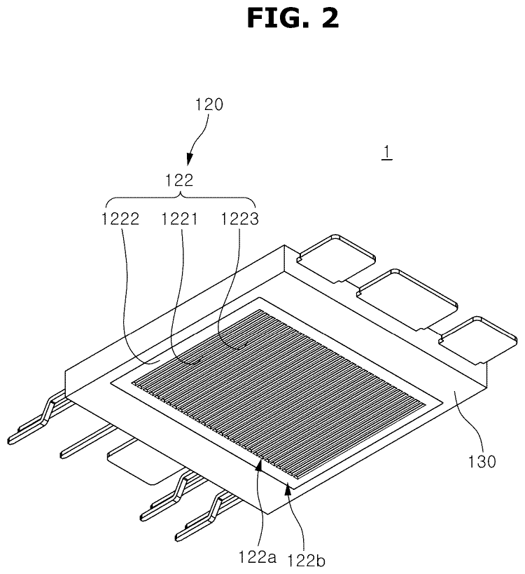

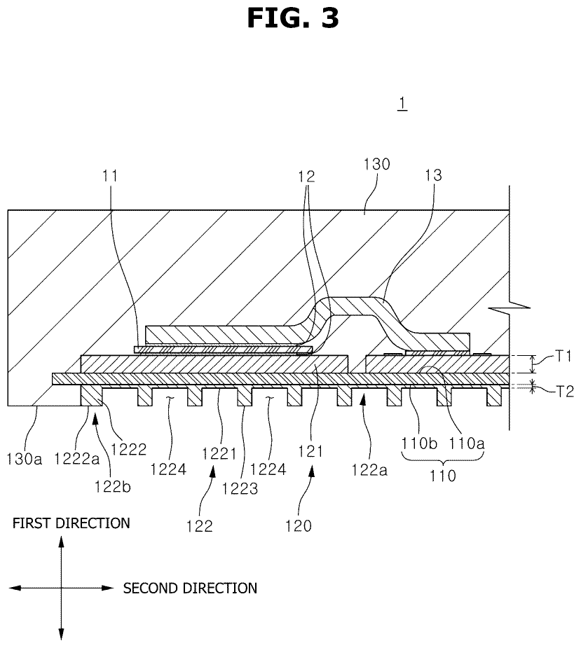

FIG. 1 is a perspective view of a power module viewed from one direction according to a first embodiment of the present disclosure, FIG. 2 is a perspective view of the power module of FIG. 1 viewed from another direction, and FIG. 3 is a cross-sectional view taken along a line III-III of FIG. 1.

Referring to FIG. 1 to FIG. 3, the power module 1 according to the first embodiment of the present disclosure includes an insulating substrate 110, a heat dissipation part 120, and a sealing part 130, which will be described in more detail below.

The insulating substrate 110 may include a direct bonded copper (DBC) substrate. The insulating substrate 110 is formed of a highly conductive metal layer, such as copper (Cu), on both sides of a ceramic substrate, and may include at least one or more layers laminated. A pattern capable of conducting electricity may be formed on a surface of the insulating substrate 110.

The insulating substrate 110 includes a first surface 110a (an upper surface based on FIG. 3) and a second surface 110b (a lower surface based on FIG. 3) disposed to face in a direction opposite to the first surface 110a.

The power module 1 according to the embodiment further includes a chip 11 and a clip 13. The chip 11 may be exemplified as a semiconductor device. The chip 11 may be formed in a structure in which a plurality of semiconductor devices are bonded in parallel to a metal interconnection formed on a predetermined substrate. The chip 11 is electrically connected to the insulating substrate 110.

The clip 13 may be used to electrically connect the chip 11 with a neighboring chip 11. When a plurality of chips 11 are disposed in parallel, the clip 13 may be bonded to each of at least two or more chips 11 disposed in parallel.

A bonding layer 12 is disposed between the clip 13 and the chip 11. The bonding layer 12 may include a heat dissipation adhesive or a thermal interface material (TIM).

A heat dissipation part 120 is integrally provided on the insulating substrate 110. The heat dissipation part 120 is in direct contact with the insulating substrate 110. The heat dissipation part 120 may dissipate heat transferred from the insulating substrate 110 to the outside of the power module 1 to cool the insulating substrate 110. The heat dissipation part 120 may include a copper (Cu) material having high thermal conductivity.

The heat dissipation part 120 includes a first heat dissipation part 121 and a second heat dissipation part 122.

The first heat dissipation part 121 may have a shape of a flat plate. The first heat dissipation part 121 may have a shape of a polygon with angled corners, such as a circle, an ellipse, or a square in a cross section.

The first heat dissipation part 121 is provided on a first surface 110a of the insulating substrate 110. In detail, the first heat dissipation part 121 is integrally provided on the first surface 110a of the insulating substrate 110. One surface (a lower surface based on FIG. 3) of the first heat dissipation part 121 facing the first surface 110a of the insulating substrate 110 may be in direct contact with the first surface 110a of the insulating substrate 110.

The chip 11 is mounted on the first heat dissipation part 121. In detail, the chip 11 is mounted on the other surface (an upper surface based on FIG. 3) of the first heat dissipation part 121. The bonding layer 12 is disposed between the first heat dissipation part 121 and the chip 11. The bonding layer 12 may include a heat dissipation adhesive or a TIM.

The second heat dissipation part 122 is disposed to be spaced apart from the first heat dissipation part 121 along a direction parallel to the first direction. The second heat dissipation part 122 is provided on the second surface 110b of the insulating substrate 110. In detail, the second heat dissipation part 122 is integrally provided on the second surface 110b of the insulating substrate 110. One surface (an upper surface based on FIG. 3) of the second heat dissipation part 122 facing the second surface 110b of the insulating substrate 110 is in direct contact with the second surface 110b of the insulating substrate 110.

The second heat dissipation part 122 may have a shape of a polygon with angled corners, such as a circle, an ellipse, or a square in a cross section. Hereinafter, an embodiment in which the cross section of the second heat dissipation part 122 is a quadrangle will be described.

The second heat dissipation part 122 includes a first part 122a and a second part 122b.

The first part 122a may refer to a central part of the second heat dissipation part 122, and the second part 122b may refer to an edge of the second heat dissipation part 122 excluding the first part 122a.

The first heat dissipation part 121 and the second heat dissipation part 122 may have different volumes. In detail, the amount of copper (Cu) constituting the first heat dissipation part 121 and the amount of copper (Cu) constituting the second heat dissipation part 122 may be different from each other. Accordingly, the first heat dissipation part 121 and the second heat dissipation part 122 may have different weights.

As another embodiment, the first heat dissipation part 121 and the second heat dissipation part 122 may have the same volume. In detail, the amount of copper (Cu) constituting the first heat dissipation part 121 and the amount of copper (Cu) constituting the second heat dissipation part 122 may be the same. Accordingly, the first heat dissipation part 121 and the second heat dissipation part 122 may have the same weight.

The first heat dissipation part 121 and the second heat dissipation part 122 have different volumes from each other or the same volume, so that the stress of the insulating substrate 110 acting in a direction parallel to the first direction and/or in a direction parallel to the second direction can be minimized due to the thermal expansion of the first heat dissipation part 121 and the second heat dissipation part 122.

The sealing part 130 is disposed to protect the chip 11 from heat, impact, and contamination, and may seal the insulating substrate 110 and a part of the heat dissipation part 120. The sealing part 130 may seal the entirety of the insulating substrate 110. The sealing part 130 may include an epoxy molding compound (EMC). Referring to FIG. 3, the top and side surfaces of the insulating substrate 110 are completely enclosed by the sealing part 130, while the bottom surface is entirely covered by the top surface of the second heat dissipation part 122, whose side surfaces are enclosed by the sealing part 130. As a result, the insulating substrate 110 is completely surrounded by the sealing part 130. In other words, the sealing part 130 seals the entirety of the insulating substrate 110.

The sealing part 130 may seal the insulating substrate 110 and the first heat dissipation part 121. Therefore, the insulating substrate 110 and the first heat dissipation part 121 are not exposed. The first heat dissipation part 121 is fixed to the insulating substrate 110 by the sealing part 130, and the contact state between the insulating substrate 110 and the first heat dissipation part 121 can be maintained. The chip 11 and the clip 13 are also sealed by the sealing part 130 not to be exposed.

The sealing part 130 may seal a part of the second heat dissipation part 122. Therefore, the remaining part of the second heat dissipation part 122 that is not sealed by the sealing part 130 may be exposed.

The second heat dissipation part 122 according to the embodiment includes a first heat dissipation body part 1221, a second heat dissipation body part 1222, and heat dissipation fin parts 1223.

The first heat dissipation body part 1221 is provided on the first part 122a of the second heat dissipation part 122. The first heat dissipation body part 1221 is in contact with the second surface 110b of the insulating substrate 110. One surface (an upper surface based on FIG. 3) of the first heat dissipation body part 1221 facing the second surface 110b of the insulating substrate 110 is in direct contact with the second surface 110b of the insulating substrate 110.

The first heat dissipation body part 1221 is in non-contact with the sealing part 130. In detail, the first heat dissipation body part 1221 is exposed because the first heat dissipation body part 1221 is not sealed by the sealing part 130.

The second heat dissipation body part 1222 extends from the first heat dissipation body part 1221. The second heat dissipation body part 1222 is provided on the second part 122b of the second heat dissipation part 122. A part of the second heat dissipation body part 1222 may be in contact with the sealing part 130. In detail, an outer surface (a left surface based on FIG. 3) of the second heat dissipation body part 1222 disposed to face in a direction parallel to the second direction may be sealed by the sealing part 130 by contacting the sealing part 130.

The second heat dissipation body part 1222 includes an exposed surface 1222a that is not in contact with the sealing part 130 and is not sealed by the sealing part 130. The exposed surface 1222a is disposed to face in a direction parallel to the first direction. The exposed surface 1222a may be a plane.

An O-ring or metal gasket is mounted on the exposed surface 1222a and an O-ring or metal gasket is interposed between a housing part (not shown) accommodating the power module 1 and the exposed surface 1222a, and thus, a space between the second heat dissipation body part 1222 and the housing part can be hermetically sealed.

An outer surface 130a of the sealing part 130 adjacent to the exposed surface 1222a and the exposed surface 1222a are disposed to form the same plane. In detail, the exposed surface 1222a of the second heat dissipation body part 1222 and the outer surface 130a of the sealing part 130 may have the same height.

The heat dissipation fin parts 1223 extend from the first heat dissipation body part 1221 along a direction parallel to the first direction, and a plurality of heat dissipation fin parts 1223 are disposed to be spaced apart from each other in a direction parallel to the second direction. A cooling path 1224 is formed between the plurality of heat dissipation fin parts 1223. A cooling fluid may flow through the cooling path 1224.

A height of the second heat dissipation body part 1222 parallel to the first direction and the height of the heat dissipation fin part 1223 parallel to the first direction may be the same.

The heat dissipation fin parts 1223 parallel to the second heat dissipation body part 1222 and the second heat dissipation body part 1222 are spaced apart from each other. Accordingly, the cooling path 1224 may be formed between the second heat dissipation body part 1222 and the heat dissipation fin parts 1223. The cooling fluid may flow through the cooling path 1224.

A thickness T1 of the first heat dissipation part 121 parallel to the first direction and a thickness T2 of the first heat dissipation body part 1221 parallel to the first direction may be different from each other.

The thickness T1 of the first heat dissipation part 121 and the thickness T2 of the first heat dissipation body part 1221 are different from each other, so that the stress of the insulating substrate 110 due to thermal expansion of the first heat dissipation part 121 and the second heat dissipation part 122, acting in the direction parallel to the first direction and/or in the direction parallel to the second direction can be minimized.

As another embodiment, the thickness T1 of the first heat dissipation part 121 parallel to the first direction may be thicker than the thickness T2 of the first heat dissipation body part 1221 parallel to the first direction.

The thickness T1 of the first heat dissipation part 121 and the thickness T2 of the first heat dissipation body part 1221 are the same, so that the stress of the insulating substrate 110 due to the thermal expansion of the first heat dissipation part 121 and the second heat dissipation part 122, acting in the direction parallel to the first direction and/or in the direction parallel to the second direction can be minimized.

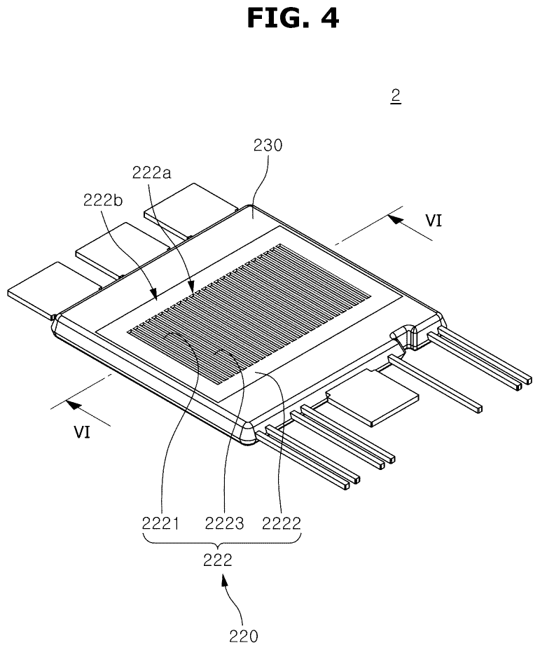

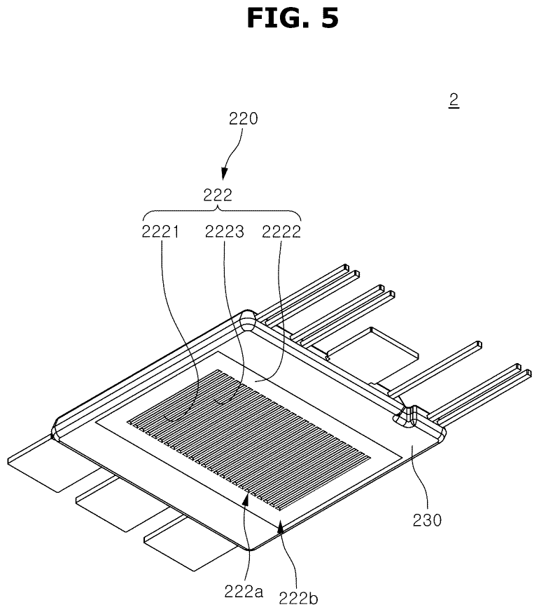

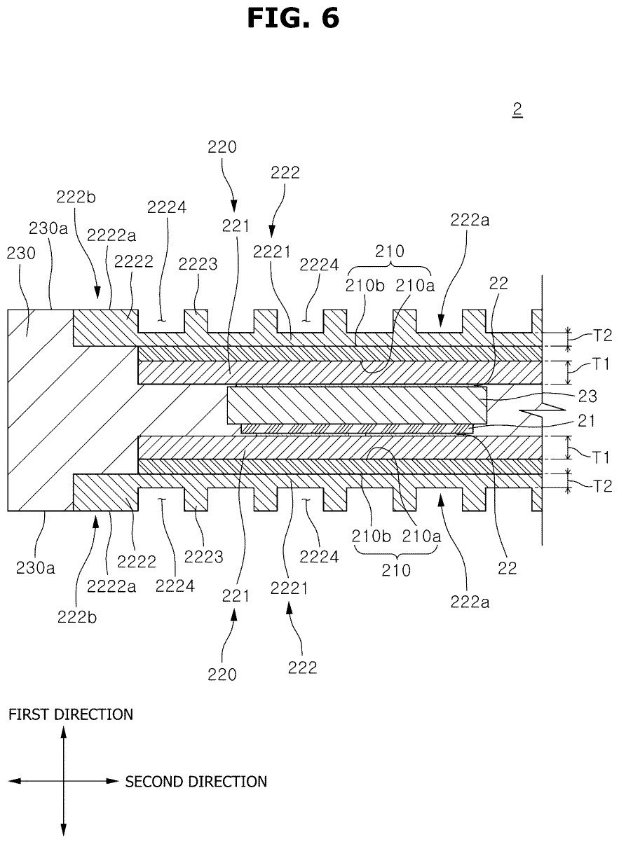

FIG. 4 is a perspective view of a power module viewed from one direction according to a second embodiment of the present disclosure, FIG. 5 is a perspective view of the power module of FIG. 4 viewed from another direction, and FIG. 6 is a cross-sectional view taken along a line ?-? of FIG. 4.

Referring to FIG. 4 to FIG. 6, the power module 2 according to the second embodiment of the present disclosure includes an insulating substrate 210, heat dissipation parts 220, and a sealing part 230.

The insulating substrate 210 may include a DBC (Direct Bonded Copper) substrate. The insulating substrate 210 is formed of a highly conductive metal layer, such as copper, on both sides of a ceramic substrate, and may include at least one or more layers laminated. A pattern capable of conducting electricity may be formed on a surface of the insulating substrate 210.

A plurality of insulating substrates 210 may be provided. At least one pair of insulating substrates 210 may be disposed to be spaced apart from each other along a direction parallel to a first direction.

The insulating substrate 210 includes a first surface 210a and a second surface 210b disposed to face in a direction opposite to the first surface 210a.

The power module 2 according to the embodiment further includes a chip 21. The chip 21 may be exemplified as a semiconductor device. The chip 21 may be formed in a structure in which a plurality of semiconductors are bonded in parallel to a metal interconnection formed on a predetermined substrate. The chip 21 is electrically connected to the insulating substrate 210.

A plurality of heat dissipation parts 220 may be provided. At least one pair of heat dissipation parts 220 may be spaced apart from each other along a direction parallel to the first direction and may be disposed to face in opposite directions.

The heat dissipation parts 220 are integrally provided on the insulating substrate 210. The heat dissipation parts 220 are in direct contact with the insulating substrate 210. The heat dissipation parts 220 dissipate heat transferred from the insulating substrate 210 to the outside of the power module 2 to cool the insulating substrate 210. The heat dissipation part 220 may include a copper (Cu) material having high thermal conductivity.

The heat dissipation parts 220 include a first heat dissipation part 221 and a second heat dissipation part 222.

The first heat dissipation part 221 may have a shape of a flat plate. The first heat dissipation part 221 may have a shape of a polygon with angled corners, such as a circle, an ellipse, or a square in a cross section.

The first heat dissipation part 221 is provided on a first surface 210a of the insulating substrate 210. In detail, the first heat dissipation part 221 is integrally provided on the first surface 210a of the insulating substrate 210. One surface of the first heat dissipation part 221 facing the first surface 210a of the insulating substrate 210 may be in direct contact with the first surface 210a of the insulating substrate 210.

The chip 21 is mounted on the first heat dissipation part 221. In detail, the chip 11 is mounted on one of the first heat dissipation parts 221 among the pair of first heat dissipation parts 221 disposed to be spaced apart from each other along the direction parallel to the first direction. A bonding layer 22 is disposed between the first heat dissipation part 221 and the chip 21. The bonding layer 22 may include a heat dissipation adhesive or a TIM.

The power module 2 according to the embodiment further includes a spacer 23. The spacer 23 is disposed between the first heat dissipation part 221 on which the chip 21 is not mounted among the pair of first heat dissipation parts 221 disposed to be spaced apart from each other along the direction parallel to the first direction and the chip 21, and may be used to insulate the chip 21.

The bonding layer 22 is disposed between the spacer 23 and the first heat radiating part 221 on which the chip 21 is not mounted. The bonding layer 22 may include a heat dissipation adhesive or a TIM.

The second heat dissipation part 222 is disposed to be spaced apart from the first heat dissipation part 221 along the direction parallel to the first direction. The second heat dissipation part 222 is provided on the second surface 210b of the insulating substrate 210. In detail, the second heat dissipation part 222 is integrally provided on the second surface 210b of the insulating substrate 210. One surface of the second heat dissipation part 222 facing the second surface 210b of the insulating substrate 210 is in direct contact with the second surface 210b of the insulating substrate 210.

The second heat dissipation part 222 may have a shape of a polygon with angled corners, such as a circle, an ellipse, or a square in a cross section. Hereinafter, an embodiment in which the cross section of the second heat dissipation part 222 is a quadrangle will be described.

The second heat dissipation part 222 includes a first part 222a and a second part 222b.

The first part 222a may refer to a central part of the second heat dissipation part 222, and the second part 222b may refer to an edge of the second heat dissipation part 222 excluding the first part 222a.

The first heat dissipation part 221 and the second heat dissipation part 222 may have different volumes. In detail, the amount of copper (Cu) constituting the first heat dissipation part 221 and the amount of copper (Cu) constituting the second heat dissipation part 222 may be different from each other. Accordingly, the first heat dissipation part 221 and the second heat dissipation part 222 may have different weights.

As another embodiment, the first heat dissipation part 221 and the second heat dissipation part 222 may have the same volume. In detail, the amount of copper (Cu) constituting the first heat dissipation part 221 and the amount of copper (Cu) constituting the second heat dissipation part 222 may be the same. Accordingly, the first heat dissipation part 221 and the second heat dissipation part 222 may have the same weight.

The first heat dissipation part 221 and the second heat dissipation part 222 have different volumes from each other or the same volume, so that the stress of the insulating substrate 210 due to thermal expansion of the first heat dissipation part 221 and the second heat dissipation part 222, acting in the direction parallel to the first direction and/or in the direction parallel to the second direction can be minimized.

The sealing part 230 is disposed to protect the chip 21 from heat, impact, and contamination, and may seal the insulating substrate 210 and a part of the heat dissipation part 220. The sealing part 230 may seal the entirety of the insulating substrate 210. The sealing part 230 may include an EMC (Epoxy Molding Compound). Referring to FIG. 6, the first surface 210a and side surfaces of the insulating substrate 210 are completely enclosed by the sealing part 230, while the second surface 210b is entirely covered by the surface of the second heat dissipation part 222 that faces the insulating substrate 210. The side surfaces of the second heat dissipation part 222 are also enclosed by the sealing part 230. As a result, the insulating substrate 210 is completely surrounded by the sealing part 230. In other words, the sealing part 230 seals the entirety of the insulating substrate 210.

The sealing part 230 may seal the insulating substrate 210 and the first heat dissipation part 221. Therefore, the insulating substrate 210 and the first heat dissipation part 221 are not exposed. The first heat dissipation part 221 is fixed to the insulating substrate 210 by the sealing part 230, and the contact state between the insulating substrate 210 and the first heat dissipation part 221 may be maintained. The chip 21 and the spacer 23 are also sealed by the sealing part 230 not to be exposed.

The sealing part 230 may seal a part of the second heat dissipation part 222. Therefore, the remaining part of the second heat dissipation part 222 that is not sealed by the sealing part 230 may be exposed.

The second heat dissipation part 222 according to the embodiment includes a first heat dissipation body part 2221, a second heat dissipation body part 2222, and heat dissipation fin parts 2223.

The first heat dissipation body part 2221 is provided on the first part 222a of the second heat dissipation part 222. The first heat dissipation body part 2221 is in contact with the second surface 210b of the insulating substrate 210. One surface of the first heat dissipation body part 2221 facing the second surface 210b of the insulating substrate 210 is in direct contact with the second surface 210b of the insulating substrate 210.

The first heat dissipation body part 2221 is in non-contact with the sealing parts 230. In detail, the first heat dissipation body part 2221 is exposed because the first heat dissipation body part 2221 is not sealed by the sealing part 230.

The second heat dissipation body part 2222 extends from the first heat dissipation body part 2221. The second heat dissipation body part 2222 is provided on the second part 222b of the second heat dissipation part 222. A part of the second heat dissipation body part 2222 may be in contact with the sealing part 230. In detail, an outer surface of the second heat dissipation body part 2222 disposed to face in a direction parallel to the second direction may be sealed by the sealing part 230 by contacting the sealing part 230.

The second heat dissipation body part 2222 includes an exposed surface 2222a that is not in contact with the sealing part 230 and is not sealed by the sealing part 230. The exposed surface 2222a is disposed to face in the direction parallel to the first direction. The exposed surface 2222a may be a plane.

An O-ring or metal gasket is mounted on the exposed surface 2222a and an O-ring or metal gasket is interposed between the housing part (not shown) accommodating the power module 2 and the exposed surface 2222a, and thus, a space between the second heat dissipation body part 2222 and the housing part can be hermetically sealed.

An outer surface 230a of the sealing part 230 adjacent to the exposed surface 2222a and the exposed surface 2222a are disposed to form the same plane. In detail, the exposed surface 2222a of the second heat dissipation body part 2222 and the outer surface 230a of the sealing part 230 may have the same height.

The heat dissipation fin parts 2223 extend from the first heat dissipation body part 2221 along the direction parallel to the first direction, and a plurality of heat dissipation fin parts 1223 are disposed to be spaced apart from each other in the direction parallel to the second direction. A cooling path 2224 is formed between the plurality of heat dissipation fin parts 2223. A cooling fluid may flow through the cooling path 2224.

A height of the second heat dissipation body part 2222 parallel to the first direction and the height of the heat dissipation fin part 2223 parallel to the first direction may be the same.

The heat dissipation fin parts 2223 parallel to the second heat dissipation body part 2222 and the second heat dissipation body part 2222 mare spaced apart from each other. Accordingly, the cooling path 2224 may be formed between the second heat dissipation body part 2222 and the heat dissipation fin part 2223. The cooling fluid may flow through the cooling path 2224.

A thickness T1 of the first heat dissipation part 221 parallel to the first direction and a thickness T2 of the first heat dissipation body part 2221 parallel to the first direction may be different from each other.

The thickness T1 of the first heat dissipation part 221 and the thickness T2 of the first heat dissipation body part 2221 are different from each other, so that the stress of the insulating substrate 210 due to thermal expansion of the first heat dissipation part 221 and the second heat dissipation part 222, acting in the direction parallel to the first direction and/or in the direction parallel to the second direction can be minimized.

As another embodiment, the thickness T1 of the first heat dissipation part 221 parallel to the first direction may be thicker than the thickness T2 of the first heat dissipation body part 2221 parallel to the first direction.

The thickness T1 of the first heat dissipation part 221 and the thickness T2 of the first heat dissipation body part 2221 are the same, so that the stress of the insulating substrate 210 due to thermal expansion of the first heat dissipation part 221 and the second heat dissipation part 222, acting in the direction parallel to the first direction and/or in the direction parallel to the second direction can be minimized.

The power modules 1 and 2 according to the embodiments of the present disclosure can reduce thermal resistance by the configurations of the heat dissipation parts 120 and 220 integrally provided on the insulating substrates 110 and 210, thereby improving heat dissipation performance and simplifying components and structures.

Although exemplary embodiments of the present disclosure have been disclosed for illustrative purposes, these are merely exemplary, and those skilled in the art will appreciate that various modifications, additions and substitutions are possible, without departing from the scope and spirit of the present disclosure as defined in the accompanying claims. Thus, the true technical scope of the present disclosure should be defined by the following claims.

What is claimed is:

1. A power module comprising:
an insulating substrate;
a heat dissipation part integrally provided on the insulating substrate; and
a sealing part that seals the insulating substrate and a part of the heat dissipation part.

2. The power module of claim 1, wherein the heat dissipation part comprises:
a first heat dissipation part integrally provided on a first surface of the insulating substrate; and
a second heat dissipation part integrally provided on a second surface of the insulating substrate, the second surface facing in a direction opposite to the first surface,
wherein the sealing part seals the entirety of the insulating substrate and the first heat dissipation part and a part of the second heat dissipation part.

3. The power module of claim 2, wherein the first heat dissipation part and the second heat dissipation part have different volumes.

4. The power module of claim 2, wherein a volume of the first heat dissipation part and a volume of the second heat dissipation part are the same.

5. The power module of claim 2, wherein the second heat dissipation part comprises:
a first heat dissipation body part contacting the second surface and not contacting the sealing part;
a second heat dissipation body part extending from the first heat dissipation body part and capable of contacting the second surface and the sealing part; and
one or more heat dissipation fin parts extending from the first heat dissipation body part in a direction parallel to a first direction, and disposed to be spaced apart from each other along a direction parallel to a second direction crossing the first direction.

6. The power module of claim 5,
wherein the first heat dissipation body part is disposed on a first part of the second heat dissipation body part,
wherein the second heat dissipation body part is disposed on a second part of the second heat dissipation body part excluding the first part of the second heat dissipation body part, and
wherein a height of the second heat dissipation body part parallel to the first direction and a height of the heat dissipation fin part parallel to the first direction are the same.

7. The power module of claim 5, wherein a thickness of the first heat dissipation part parallel to the first direction and a thickness of the first heat dissipation body part parallel to the first direction are different from each other.

8. The power module of claim 5, wherein a thickness of the first heat dissipation part parallel to the first direction is greater than a thickness of the first heat dissipation body part parallel to the first direction.

9. The power module of claim 5,
wherein the second heat dissipation body part comprises an exposed surface that does not contact the sealing part, and
wherein an outer surface of the sealing part adjacent to the exposed surface and the exposed surface are disposed on a same plane.

10. The power module of claim 1,
wherein the insulating substrate and the heat dissipation part are disposed in plural numbers to be spaced apart from each other along a direction parallel to a first direction, and
wherein the plurality of heat dissipation parts are disposed to face in opposite directions.
